(19) United States
(12) Patent Application Publication
(10) Pub. No.: US 2025/0330138 A1
(43) Pub. Date: Oct. 23, 2025

(54) QUARTZ OSCILLATOR

(71) Applicant: TXC Corporation, Taipei City (TW)

(72) Inventors: Wun-Kai Wang, Taipei City (TW); Cheng-Wei Lin, Taipei City (TW); Chih-Hung Chiu, Taipei City (TW)

(73) Assignee: TXC Corporation, Taipei City (TW)

(21) Appl. No.: 18/668,255

(22) Filed: May 20, 2024

(30) Foreign Application Priority Data
Apr. 19, 2024 (TW) 113114685

(51) Int. Cl. H03H 9/02; H03H 9/19

(52) U.S. Cl. CPC H03H 9/02653; H03H 9/02023; H03H 9/19

(57) ABSTRACT

Disclosed is a quartz oscillator including a first cover, a second cover, and a quartz oscillation device. The quartz oscillation device is disposed between the first cover and the second cover. The quartz oscillation device includes a quartz sheet, a first conductive layer and a second conductive layer. The first conductive layer is disposed on the first surface of the quartz sheet. The second conductive layer is disposed on the second surface of the quartz sheet. The quartz sheet has a groove or an opening penetrating therethrough. An included angle between a side wall of the groove or the opening and the first surface or the second surface is 60° to 90°.

### CROSS-REFERENCE TO RELATED APPLICATION

This application claims the priority benefit of Taiwan application serial no. 113114685, filed on Apr. 19, 2024. The entirety of the above-mentioned patent application is hereby incorporated by reference herein and made a part of this specification.

### BACKGROUND

### Technical Field

The present disclosure relates to a quartz oscillator, and in particular to a quartz oscillation device whose quartz sheet has a groove or an opening with a sidewall having a specific angle range.

### Description of Related Art

A quartz oscillator is an electronic device provided to generate an oscillation frequency. A manufacturing method of a quartz oscillator is generally performed by cutting a corresponding quartz plate appropriately to form an appropriate groove or an opening pattern. Then, the groove or the opening pattern is packaged or cut to form a corresponding quartz oscillation device or a quartz oscillator.

However, as the current design for electronic products is towards lighter, thinner and shorter, the size of the quartz oscillation device in electronic products should be reduced accordingly. However, in the process of forming grooves or openings of quartz oscillation devices, the morphology of the grooves or openings is often a key factor affecting the quality or yield of the quartz oscillation devices or quartz oscillators. Therefore, how to improve the quality or reliability of quartz oscillation devices is indeed an issue to be solved.

### SUMMARY

The present disclosure provides a quartz oscillator with improved quality or reliability.

A quartz oscillator of the present disclosure includes a first cover, a second cover, and a quartz oscillation device. The quartz oscillation device is disposed between the first cover and the second cover. The quartz oscillation device includes a quartz sheet, a first conductive layer and a second conductive layer. The first conductive layer is disposed on a first surface of the quartz sheet. The second conductive layer is disposed on a second surface of the quartz sheet. The quartz sheet has a groove or an opening penetrating therethrough. An included angle between a sidewall of the groove or the opening and the first surface or the second surface is 60° to 90°.

Based on the above, since the sidewall of the groove or the opening of the quartz sheet has an included angle of 60° to 90°, the quartz oscillator including the quartz sheet has improved quality, and has improved reliability in application.

### BRIEF DESCRIPTION OF THE DRAWINGS

FIG. 1A is a schematic top view of a partial manufacturing method of a quartz oscillator according to the first embodiment of the present disclosure.

FIG. 1B to FIG. 1E are partial cross-sectional schematic views of a partial manufacturing method of a quartz oscillator according to the first embodiment of the present disclosure.

FIG. 2 is a schematic cross-sectional view of a quartz oscillator according to the second embodiment of the present disclosure.

FIG. 3A to FIG. 3C are partial cross-sectional schematic views of a partial manufacturing method of a quartz oscillator according to the third embodiment of the present disclosure.

FIG. 4 is a schematic cross-sectional view of a quartz oscillator according to the fourth embodiment of the present disclosure.

FIG. 5 is a schematic top view of a quartz oscillator according to an embodiment of the present disclosure.

### DESCRIPTION OF THE EMBODIMENTS

In the drawings, the size or aspect of some devices or layers might be enlarged, reduced, or exaggerated for the purpose of clarity. For example, the inclination angle and/or width of the groove or opening might be exaggeratedly illustrated in subsequent drawings. Moreover, the numerical value expressed in the specification may include the stated numerical value and the deviation value within the range of deviation acceptable to those having ordinary skill in the art. The above deviation value may be one or a plurality of standard deviations in the manufacturing process or measurement process or the calculation error caused by other factors such as the number of digits used, rounding, or error propagation in the calculation or conversion process.

Moreover, directional terms (e.g., up or down) used in the specification only refer to the directions in the reference drawings. Thus, unless otherwise specified, the directional terms are used to illustrate rather than limit the disclosure. Furthermore, in order to clearly indicate the directional relationship between different drawings, a Cartesian coordinate system (XYZ coordinate system) is exemplarily used in some of the diagrams to represent the corresponding directions, but the disclosure is not limited thereto.

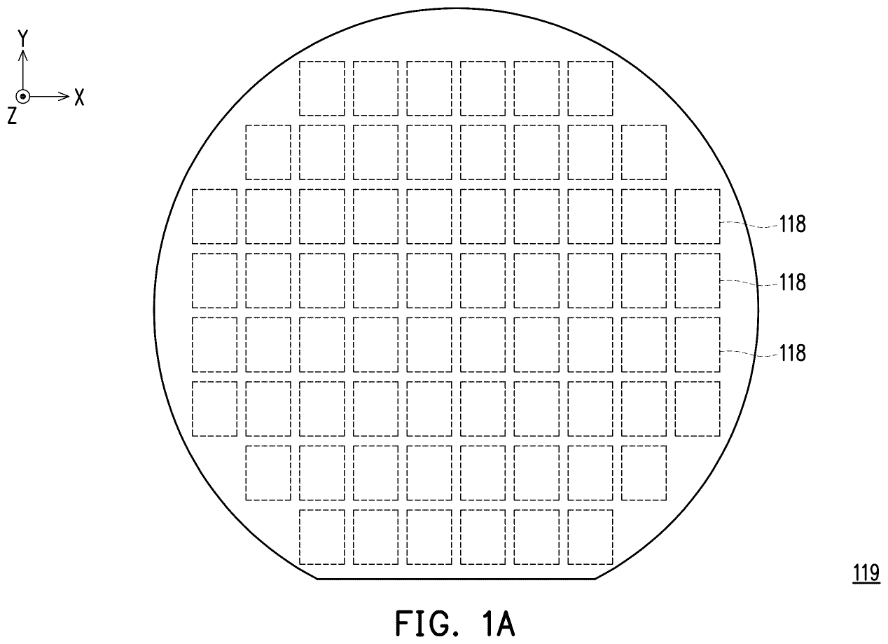

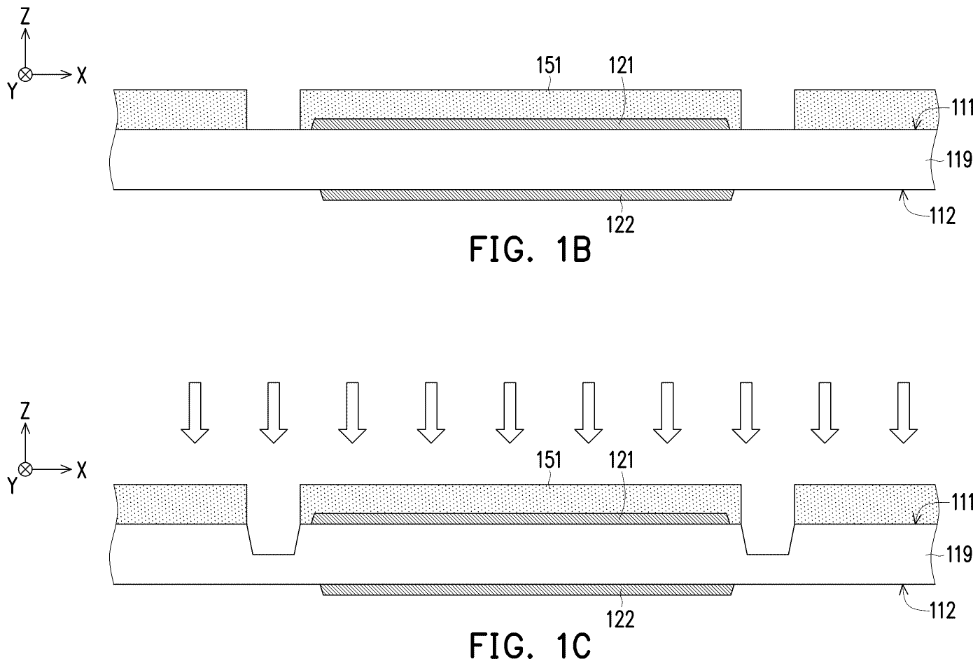

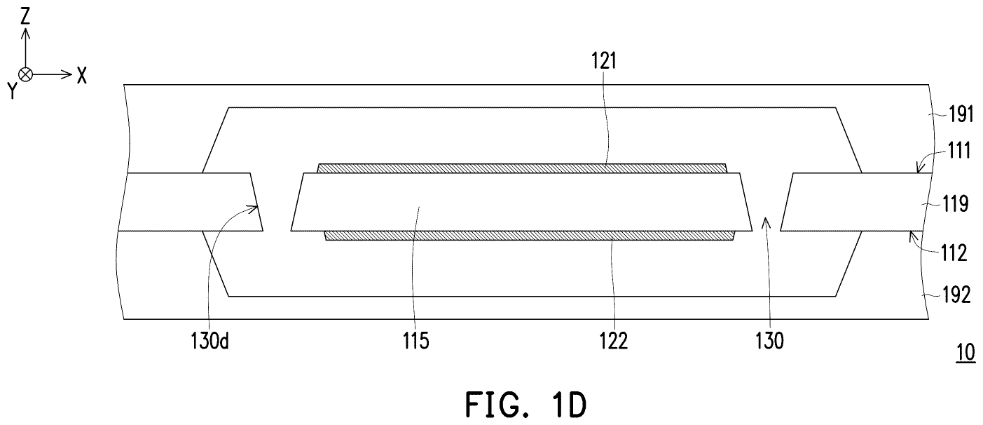

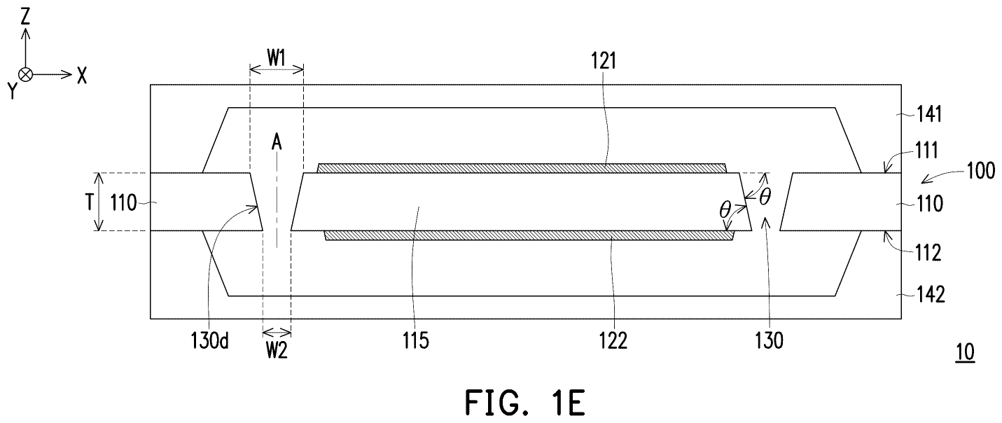

FIG. 1A is a schematic top view of a partial manufacturing method of a quartz oscillator according to the first embodiment of the present disclosure. FIG. 1B to FIG. 1E are partial cross-sectional schematic views of a partial manufacturing method of a quartz oscillator according to the first embodiment of the present disclosure.

Referring to FIG. 1A, a quartz plate 119 is provided. The quartz plate 119 may be divided into a plurality of device areas 118. In subsequent processes, each of the device areas 118 may be respectively subjected to appropriate processes, so that each of the device areas 118 becomes a corresponding quartz oscillation device (such as the quartz oscillation device 100 shown in FIG. 1D or other similar quartz oscillation devices). In addition, for the purpose of simplicity, not all of the device areas 118 are shown one by one in FIG. 1A. Moreover, in subsequent cross-sectional views (e.g., FIG. 1B to FIG. 1D), a single device area 118 is correspondingly shown or described.

In an embodiment, the quartz plate 119 may be a quartz wafer. The quartz wafer may have corresponding flats or notches, but the disclosure is not limited thereto.

In an embodiment, the thickness of the quartz plate 119 may be adjusted depending on the requirements of the quartz oscillation device 100 in subsequent process. For example, the thickness of the quartz plate 119 may be approximately 20 micrometers (um) to 50 μm. In addition, the present disclosure does not limit the thickness of the quartz plate 119 to be entirely the same.

Referring to FIG. 1B, a corresponding patterned conductive layer may be formed on the quartz plate 119 (shown in FIG. 1A) through appropriate methods (such as plating and photolithography). For example, a corresponding first conductive layer 121 may be formed on the first surface 111 of the quartz plate 119, and a corresponding second conductive layer 122 may be formed on the second surface 112 (lower part in the figure) of the quartz plate 119. That is to say, the quartz plate 119 may be sandwiched between the first conductive layer 121 and the second conductive layer 122. The layout design of the first conductive layer 121 or the second conductive layer 122 may be adjusted depending on the requirement of the quartz oscillation device 100 in the subsequent process, and is not limited in the present disclosure.

Please continue to refer to FIG. 1B, a corresponding mask layer 151 may be formed or configured on the first surface 111 of the quartz plate 119. The mask layer 151 may expose a portion of the first surface 111 for subsequent etching processes.

In an embodiment, the mask layer 151 may be a patterned photoresist layer formed on the quartz plate 119. The patterned photoresist layer may cover the first conductive layer 121 and a portion of the first surface 111 exposed by the first conductive layer 121.

In an embodiment, the mask layer 151 may be a preformed metal mask, and the pattern of the metal mask may be formed by an appropriate method (such as laser engraving). In addition, the metal mask may be disposed on the first conductive layer 121 and/or on the portion of the first surface 111 exposed by the first conductive layer 121 through an appropriate method (such as adhesion).

Referring to FIG. 1C to FIG. 1D, a portion of the quartz plate 119 is removed through a corresponding dry etching process to form a corresponding groove or an opening 130 (shown in FIG. 1D). The groove or the opening 130 may be formed by removing a portion of the quartz plate 119 in a direction from the first surface 111 toward the second surface 112. As a result, as shown in FIG. 1D, the minimum width (which may be referred to as: the first width W1) of the groove or the opening 130 on the first surface 111 may be greater than or equal to the minimum width (which may be referred to as: the second width W2) of the groove or the opening 130 on the second surface 112.

Compared with the wet etching process, the dry etching process is less likely to (which does not mean absolutely unlikely) cause side etching or undercut. Moreover, compared with the wet etching process, it is more possible for the dry etching process to adjust or control the direction or angle for dry etching by using a corresponding etching agent. In this way, the corresponding angle may be controlled more easily through the corresponding dry etching process, so that the axial angles at different etching positions (that is, the direction or angle of the virtual intermediate axis corresponding to the two opposite sides on the cross section) may be more consistent. In addition, a more preferable aspect ratio may be realized. In this way, the manufactured quartz oscillation device 100 may have improved quality and/or yield. It is worth noting that in some dry etching processes (such as laser drilling or mechanical drilling), the mask layer 151 is not necessarily required.

In an embodiment, the dry etching process may include a reactive ion etching (RIE) process, for example, Inductively Coupled Plasma-Reactive Ion Etching (ICP-RIE) process. The etching agent adopted in the RIE process may include fluorine-based etching agents. The fluorine-based etching agents include, for example, but are not limited to: trifluoromethane (CHF₃), carbon tetrafluoride (CF₄), octafluorocyclobutanec (C₄F₈), sulfur hexafluoride (SF₆), mixtures of the above, mixtures of the above with other reactive gases or noble gases (such as CF₄/O₂, SF₆/Ar or C₄F₈/He). Compared with the mechanical drilling process or the powder blasting process, the RIE process is less likely to cause corresponding breakage or cracks during the etching process because of the influence of stress or material. Compared with the laser drilling process, the RIE process is less likely to cause corresponding breakage or cracks during the etching process because of heat concentration (for example, heat is generated in a local area due to the absorption of laser light on the material) or the influence of material.

Referring to FIG. 1D, after forming the corresponding groove or opening 130, the corresponding mask layer 151 (if any) may be removed by an appropriate method.

Referring to FIG. 1D, after forming the corresponding groove or opening 130, the first plate 191 and the second plate 192 may be configured so that the quartz plate 119 is sandwiched therebetween.

In an embodiment, the first plate 191 or the second plate 192 may have appropriate circuits (not shown), but the disclosure is not limited thereto. The aforementioned circuits may include, but are not limited to: circuits located on a single surface of the plate, circuits located on two opposite surfaces, and/or conductive vias penetrating the plate. The layout design of the circuit may be adjusted as required and is not limited in the present disclosure.

In an embodiment, the first plate 191 or the second plate 192 may be directly or indirectly connected to the quartz plate 119. For example, a portion of the first plate 191 or a portion of the second plate 192 may directly contact a portion of the quartz plate 119. For example, there may be a corresponding sealing material (not shown) or a sealing ring (not shown) between the first plate 191 and the quartz plate 119 or between the second plate 192 and the quartz plate 119.

In an embodiment, the material of the first plate 191 or the second plate 192 may include quartz or other suitable materials, but the disclosure is not limited thereto. In an embodiment, the size or shape of the first plate 191 or the second plate 192 may be the same as or similar to the quartz plate 119.

Please refer to FIG. 1D to FIG. 1E. The structure shown in FIG. 1D may be subjected to a singulation process in an appropriate manner to form a corresponding quartz oscillator 10. The aforementioned singulation process includes, for example, performing appropriate cutting corresponding to each of the device areas of the quartz plate 119 and the first plate 191/second plate 192 to form the corresponding quartz oscillation device 100 and the first cover 141/second cover 142.

After the above process, the production of the quartz oscillator 10 of this embodiment may be substantially completed. However, it is worth noting that the manufacturing method of the quartz oscillator 10 in FIG. 1E is not entirely limited to the above-mentioned method.

Referring to FIG. 1E, the quartz oscillator 10 includes a first cover 141, a second cover 142 and a quartz oscillation device 100. The quartz oscillation device 100 is disposed between the first cover 141 and the second cover 142. The quartz oscillation device 100 includes a quartz sheet 110, a first conductive layer 121 and a second conductive layer 122. The first conductive layer 121 is disposed on the first surface 111 of the quartz sheet 110. The second conductive layer 122 is disposed on the second surface 112 of the quartz sheet 110. The quartz sheet 110 has a groove or an opening 130 penetrating therethrough. On a cross section (as shown in FIG. 1E), an included angle θ between a sidewall 130d of the groove or the opening 130 and the first surface 111 or the second surface 112 is 60° to 90° (might be close to 90° but not) 90°. It is worth noting that in terms of angle measurement, the aforementioned first surface 111 or the second surface 112 may generally refer to a virtual surface extending from the first surface 111 or the second surface 112 (one of the first surface 111 or the second surface 112), or the virtual surface parallel to the first surface 111 or the second surface 112. Moreover, the corresponding included angle θ may be acquired through a direct measurement method (for example: measuring with an optical microscope or electron microscope after cutting) or an indirect measurement method (for example: after confirming the position of the groove or the opening 130 on the first surface 111 and the second surface 112, estimation is performed through trigonometric functions).

In an embodiment, the included angle θ may be about 60°, 65°, 70°, 75°, 80°, 85°, close to 90° but not 90°, or a range between any two of the numeral values, or a corresponding value in the range between any two of the numeral values.

In an embodiment, for the groove or the opening 130 formed by the RIE process, the included angle θ may be between 80° and 90° (but may be close to 90° but not) 90°.

In an embodiment, the minimum width (which may be referred to as: the first width W1) of the groove or the opening 130 on the first surface 111 may be greater than or equal to the minimum width (which may be referred to as: the second width W2) of the groove or the opening 130 on the second surface 112. In an embodiment, the second width W2 may be approximately 80% to 100% of the first width W1. In an embodiment, for the groove or the opening 130 formed by the RIE process, the second width W2 may be approximately 99% to 100% of the first width W1.

In an embodiment, the included angle between the middle axis A of the groove or the opening 130 and the first surface 111 or the second surface 112 is 75° to 90°. In an embodiment, for the groove or the opening 130 formed by the RIE process, the included angle between the middle axis A and the first surface 111 or the second surface 112 may further range from 83° to 90°.

In an embodiment, on a cross section (as shown in FIG. 1D), the sidewall 130d of the groove or the opening 130 is substantially a corresponding flat surface.

In an embodiment, on a cross section (as shown in FIG. 1D), the depth (which may correspond to the thickness T of the quartz sheet 110 where the groove or the opening 130 is formed) of the groove or the opening 130 is at least about 1.5 times or more the minimum width of the groove or the opening 130. In an embodiment, on a cross section (as shown in FIG. 1D), the depth (which may correspond to the thickness T of the quartz sheet 110 where the groove or the opening 130 is formed) of the groove or the opening 130 may further be about 6 times or more the minimum width of the groove or the opening 130. In an embodiment, on a cross section (as shown in FIG. 1D), the depth of the groove or the opening 130 is 6 to 10 times the minimum width of the groove or the opening 130. In an embodiment, the depth (which may correspond to the thickness T of the quartz sheet 110 where the groove or the opening 130 is formed) of the groove or the opening 130 may be approximately 80 μm. In an embodiment, the minimum width of the groove or the opening 130 may be approximately 10 μm to 20 μm.

In an embodiment, the first cover 141 and/or the second cover 142 may have corresponding concaves, and the concaves face and correspond to the oscillation area 115 of the quartz sheet 110.

In an embodiment, the first cover 141 and/or the second cover 142 may have appropriate circuits (not shown), and the circuits may be electrically connected to the first conductive layer 121 and/or the second conductive layer 122 correspondingly.

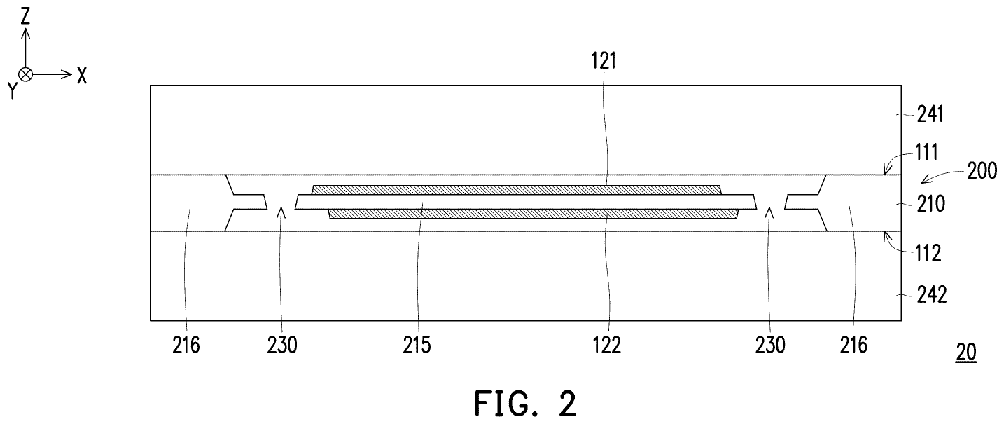

FIG. 2 is a schematic cross-sectional view of a quartz oscillator according to the second embodiment of the present disclosure. The quartz oscillator 20 in this embodiment may be the same as or similar to the aforementioned quartz oscillator 10 in terms of structure or manufacturing method. Similar structures or elements are denoted by the same reference numerals, and related descriptions are omitted.

Referring to FIG. 2, the quartz oscillator 20 includes a first cover 241, a second cover 242 and a quartz oscillation device 200. The quartz oscillation device 200 is disposed between the first cover 241 and the second cover 242. The quartz oscillation device 200 includes a quartz sheet 210, a first conductive layer 121 and a second conductive layer 122. The first conductive layer 121 is disposed on the first surface 111 of the quartz sheet 110. The second conductive layer 122 is disposed on the second surface 112 of the quartz sheet 210. The quartz sheet 210 has a groove or an opening 230 penetrating therethrough. The appearance or cross-sectional shape of the groove or the opening 230 may be the same as or similar to that of the aforementioned groove or opening 130 (for example, having an included angle of 60° to) 90°.

In this embodiment, the material, size and/or corresponding configuration (such as: circuit relationship) of the first cover 241 and/or the second cover 242 may be the same as or similar to that of the first cover 141 and/or the second cover 142, so no further description will be given here.

In this embodiment, the thickness of the oscillation area 215 of the quartz sheet 210 is smaller than the thickness of the periphery area 216 of the quartz sheet 210.

In an embodiment, the thickness of the oscillation area 215 of the quartz sheet 210 is smaller than the thickness of the periphery area 216 of the quartz sheet 210, and the first cover 241 and/or the second cover 242 may be a solid structure similar to a rectangular cuboid (i.e., not an inverted U-shape, U-shape or the like), so that it is possible to reduce the difficulty for bonding. In addition, since the etching process for forming concaves may be omitted, part of the process may also be simplified or omitted (such as: concave alignment).

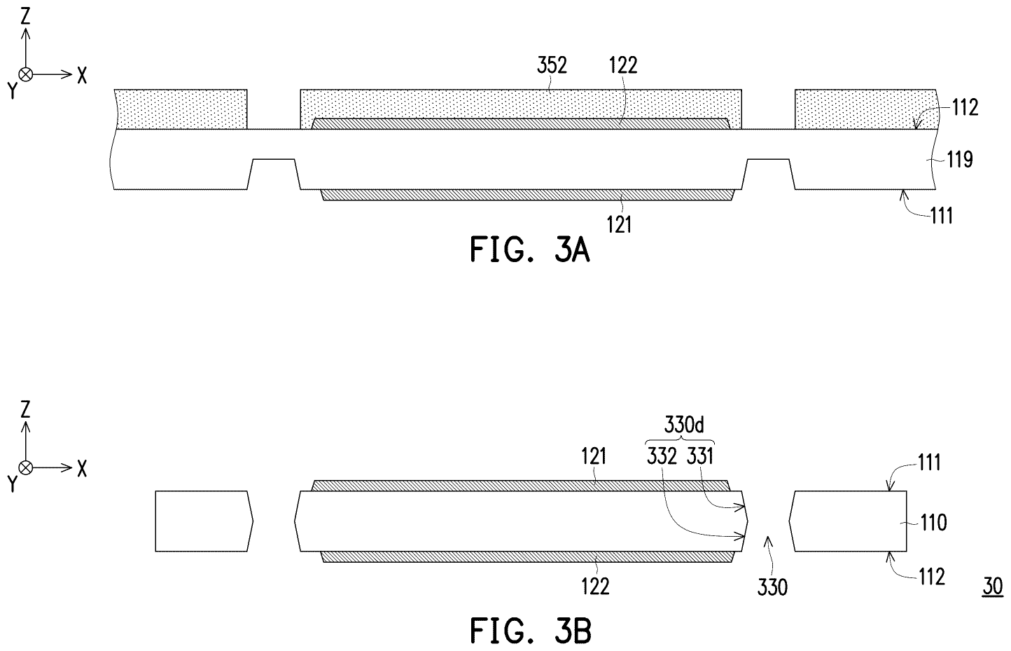

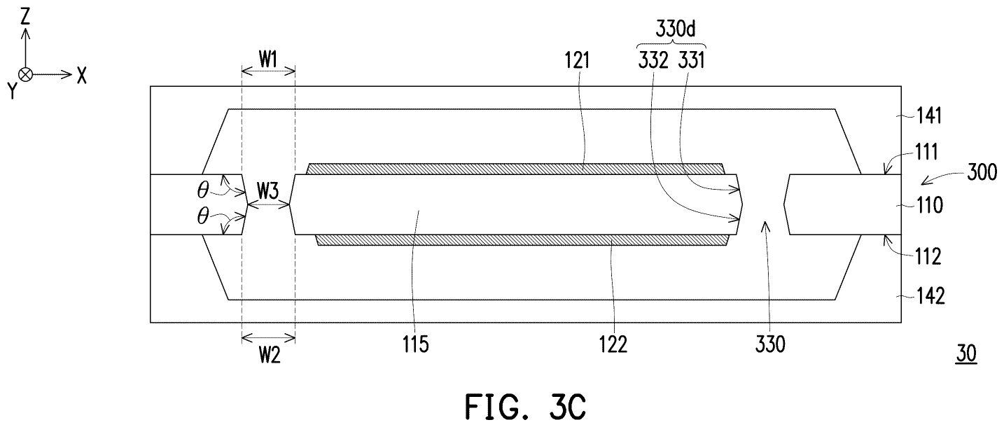

FIG. 3A to FIG. 3B are partial cross-sectional schematic views of a partial manufacturing method of a quartz oscillator according to the third embodiment of the present disclosure. The quartz oscillator 30 in this embodiment may be the same as or similar to the aforementioned quartz oscillator 10 in terms of structure or manufacturing method. Similar structures or elements are denoted by the same reference numerals, and related descriptions are omitted. For example, the manufacturing method of the quartz oscillator 30 of this embodiment may be in continuation of the method shown in FIG. 1C.

Referring to FIG. 1C and FIG. 3A, after removing a portion of the quartz plate 119 in a direction from the first surface 111 to the second surface 112, the structure as shown in FIG. 1C may be flipped upside down; then, as shown in FIG. 3A, a portion of the quartz plate 119 is removed in a direction from the second surface 112 to the first surface 111.

For example, a corresponding mask layer 352 may be formed or configured on the second surface 112 of the quartz plate 119. The mask layer 352 may expose a portion of the second surface 112 for subsequent etching processes.

It is worth noting that the mask layer 351 may be formed through appropriate steps. Taking the embodiments shown in FIG. 1C and FIG. 3A as an example, the mask layer 352 may be formed after the steps shown in FIG. 1C. In an embodiment not shown, a corresponding mask layer 352 may be formed or configured on the second surface 112 of the quartz plate 119 before removing a portion of the quartz plate 119 (as in the step shown in FIG. 1C).

Referring to FIG. 3A to FIG. 3B, the corresponding groove or the opening 130 may be formed in a manner similar to that shown in FIG. 1C to FIG. 1D.

It is worth noting that the mask layer 351 may be removed through appropriate steps. Taking the embodiments shown in FIG. 1C and FIG. 3A to FIG. 3B as an example, the mask layer 151 (shown in FIG. 1C) may be removed first, and then the mask layer 352 (shown in FIG. 3A) may be removed. In an embodiment not shown, the mask layer 151 (shown in FIG. 1C) and the mask layer 352 (shown in FIG. 3A) may be removed together through the same step.

Please continue to refer to FIG. 3B to FIG. 3C. After forming the corresponding groove or the opening 330, the first plate (not shown; the same as or similar to the first plate 191 of FIG. 1D) and the second plate (not shown; the same as or similar to the second plate 192 of FIG. 1D) may be configured in a manner similar to that shown in FIG. 1C to FIG. 1D, so that the quartz plate 119 is sandwiched therebetween. Then, the corresponding singulation process may be performed in a manner similar to that shown in FIG. 1D to FIG. 1E to form the corresponding quartz oscillator 30.

After the above process is performed, the production of the quartz oscillator 30 in the present embodiment may be substantially completed. However, it is worth noting that the manufacturing method of the quartz oscillator 30 in FIG. 3B is not entirely limited to the above-mentioned method.

Referring to FIG. 3C, the quartz oscillator 30 includes a first cover 141, a second cover 142 and a quartz oscillation device 300. The quartz oscillation device 300 is disposed between the first cover 141 and the second cover 142. The quartz oscillation device 300 includes a quartz sheet 110, a first conductive layer 121 and a second conductive layer 122. The first conductive layer 121 is disposed on the first surface 111 of the quartz sheet 110. The second conductive layer 122 is disposed on the second surface 112 of the quartz sheet 110. The quartz sheet 110 has a groove or an openings 330 penetrating therethrough. On a cross section (as shown in FIG. 3D), an included angle θ between a sidewall 330d of the groove or the opening 330 and the first surface 111 or the second surface 112 is 60° to 90°.

The manufacturing method of the quartz oscillation device 300 is similar to the manufacturing method of the quartz oscillation device 100. One difference between them may be that the formation method for the groove or the opening 330 is different. Moreover, in terms of structure, the minimum width (which may be referred to as: the first width W1) of the groove or the opening 330 on the first surface 111 may be closer to the minimum width (which may be referred to as: the second width W2) of the groove or the opening 330 on the second surface 112. For example, the ratio of the first width W1 to the second width W2 may be approximately 0.99to 1.01.

In this embodiment, the horizontal position of the narrowest part of the groove or the opening 330 is disposed between the first surface 111 and the second surface 112. In an embodiment, the width W3 at the narrowest part is approximately 99.5% to 100% of the first width W1 or the second width W2.

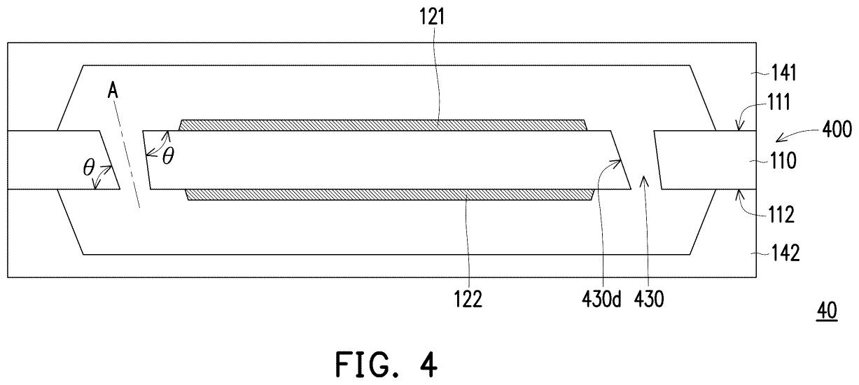

In an embodiment, on a cross section (as shown in FIG. 3C), the sidewall 330d of the groove or the opening 330 has a first portion 331 close to the first surface 111 and a second portion 332 close to the second surface 112. The first portion 331 and/or the second portion 332 are substantially corresponding flat surfaces. Briefly speaking, on a cross section (as shown in FIG. 3B), the groove or the opening 330 may be hourglass-shaped to a slight extent. FIG. 4 is a schematic cross-sectional view of a quartz oscillator according to the fourth embodiment of the present disclosure. The quartz oscillator 400 in this embodiment may be the same as or similar to the aforementioned quartz oscillator 10 in terms of structure or manufacturing method. Similar structures or elements are denoted by the same reference numerals, and related descriptions are omitted.

Referring to FIG. 4, the quartz oscillator 40 includes a first cover 141, a second cover 142 and a quartz oscillation device 400. The quartz oscillation device 400 is disposed between the first cover 141 and the second cover 142. The quartz oscillation device 40 includes a quartz sheet 110, a first conductive layer 121 and a second conductive layer 122. The first conductive layer 121 is disposed on the first surface 111 of the quartz sheet 110. The second conductive layer 122 is disposed on the second surface 112 of the quartz sheet 110. The quartz sheet 110 has the groove or the opening 130 penetrating therethrough. On a cross section (as shown in FIG. 4), an included angle θ between a sidewall 430d of the groove or the opening 430 and the first surface 111 or the second surface 112 is 60° to 90°.

The manufacturing method or corresponding structure of the quartz oscillation device 400 may be similar to the manufacturing method or corresponding structure of the quartz oscillation device 100. One difference between them may be: the angle θ between the middle axis A and the first surface 111 or the second surface 112 may be less than 90°, which might be, but is not limited to, caused by a deflection of the direction in which the etched object is placed during the formation of the groove or the opening 430, but the angle θ being less than 90° basically has no obvious impact on the structure and/or corresponding use of the quartz oscillation device 400.

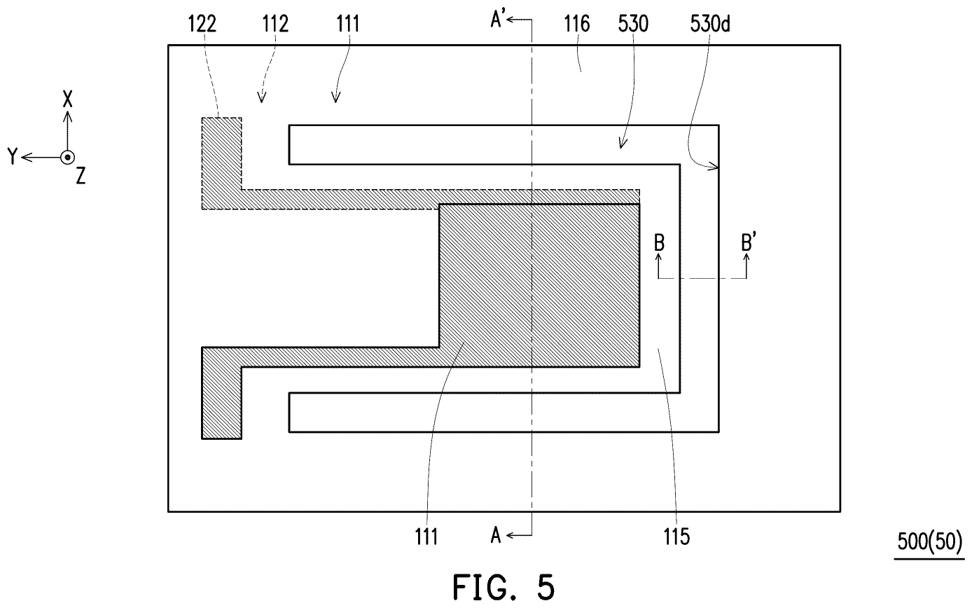

FIG. 5 is a schematic top view of a quartz oscillator according to an embodiment of the present disclosure. Specifically, FIG. 5 is a schematic top view of the corresponding quartz oscillation device.

The quartz oscillator 50 includes a first cover (not shown, which may be the same as or similar to the aforementioned first cover 141 or the first cover 241), a second cover (not shown, which may be the same as or similar to the second cover 142 or the second cover 242) and the quartz oscillation device 500. Similar to the aforementioned cross-sectional view, the quartz oscillation device 500 is disposed between the first cover and the second cover. The quartz oscillation device 500 includes a quartz sheet 110, a first conductive layer 121 and a second conductive layer 122. The quartz sheet 110 includes an oscillation area 115 and a periphery area 116. Viewed from a top direction (as shown in FIG. 5), the groove or the opening 530 may be disposed between the oscillation area 115 and the periphery area 116. The first conductive layer 121 is disposed on the first surface 111 of the quartz sheet 110. The second conductive layer 122 is disposed on the second surface 112 of the quartz sheet 110. The quartz sheet 110 has a groove or an opening 530 penetrating therethrough. Furthermore, the cross section of the quartz oscillation device 500 corresponding to the cross-sectional line A-A′ may be as shown in FIG. 1D, FIG. 2, FIG. 3B or FIG. 4. In addition, the cross section of the quartz oscillation device 500 corresponding to the cross-sectional line B-B′ may also be shown correspondingly as the groove or the opening on one side in FIG. 1E, FIG. 2, FIG. 3C or FIG. 4. In other words, the contours of the sidewall 530d of the groove or the opening 530 may be substantially consistent in different directions (the direction along the cross-sectional line A-A′ and the direction along the cross-sectional line B-B′). That is to say, the surface of the sidewall 530d of the groove or the opening 530 basically has no direct association with the lattice plane of the quartz sheet 110.

To sum up, in the quartz oscillator of the present disclosure, since the sidewall of the groove or the opening of the quartz sheet therein has an included angle of 60° to 90°, the quartz oscillator has improved quality, and has improved reliability in application.

What is claimed is:

1. A quartz oscillator, comprising:
a first cover;
a second cover; and
a quartz oscillation device disposed between the first cover and the second cover, and the quartz oscillation device comprising:
a quartz sheet;
a first conductive layer disposed on a first surface of the quartz sheet; and
a second conductive layer disposed on a second surface of the quartz sheet,
wherein the quartz sheet has a groove or an opening penetrating therethrough, and an included angle between a sidewall of the groove or the opening and the first surface or the second surface is 60° to 90°.

2. The quartz oscillator according to claim 1, wherein the groove or the opening is formed by dry etching.

3. The quartz oscillator according to claim 1, wherein an included angle between a middle axis of the groove or the opening and the first surface or the second surface is 75° to 90°.

4. The quartz oscillator according claim 1, wherein contours of the sidewall of the groove or the opening are consistent on different cross sections.

5. The quartz oscillator according to claim 1, wherein a depth of the groove or the opening is 1.5 times or more a minimum width of the groove or the opening.

6. The quartz oscillator according to claim 1, wherein on a cross-section, a width of the groove or the opening gradually increases from the second surface to the first surface.

7. The quartz oscillator according to claim 1, wherein on a cross section, the sidewall of the groove or the opening is a flat surface.

8. The quartz oscillator according to claim 1, wherein a horizontal position of a narrowest part of the groove or the opening is disposed between the first surface and the second surface.

9. The quartz oscillator according to claim 8, wherein the groove or the opening is formed by performing a dry etching process for multiple times.

10. The quartz oscillator according to claim 1, wherein the sidewall of the groove or the opening has a first portion close to the first surface and a second portion close to the second surface, and the first portion and the second portion are flat surfaces corresponding to each other.

11. The quartz oscillator according to claim 10, wherein the groove or the opening is formed by performing a dry etching process for multiple times.
